(19) United States
(12) Patent Application Publication
(10) Pub. No.: US 2014/0291597 A1
(43) Pub. Date: Oct. 2, 2014

(54) High-speed, High-density, and Low-power consumption Phase-change Memory Unit, and Preparation Method Thereof

(71) Applicant: SHANGHAI INSTITUTE OF MICROSYSTEM AND INFORMATION TECHNOLOGY, CHINESE ACADEMY, SHANGHAI (CN)

(72) Inventors: Zhitang Song, Shanghai (CN); Yifeng Gu, Shanghai (CN); San Nian Song, Shanghai (CN)

(73) Assignee: SHANGHAI INSTITUTE OF MICROSYSTEM AND INFORMATION TECHNOLOGY, CHINESE ACADEMY, SHANGHAI (CN)

(21) Appl. No.: 14/129,960

(22) PCT Filed: Dec. 27, 2012
(86) PCT No.: PCT/CN2012/087647

§ 371 Date: Dec. 28, 2013

(30) Foreign Application Priority Data
Sep. 11, 2012 (CN) 201210335325.6

(51) Int. Cl. H01L 45/00

(52) U.S. Cl. CPC H01L 45/12; H01L 45/16
USPC 257/2; 438/382

(57) ABSTRACT

The present invention provides a high-speed, high-density, and low-power consumption phase-change memory unit, and a preparation method thereof In the preparation method of the present invention, a transition material layer with an accommodation space is first prepared on a surface of a structure of a formed first electrode, where the accommodation space corresponds to the first electrode; a phase-change material layer is then prepared on a structure of the formed transition material layer, and the phase-change material layer is enabled to be in the accommodation space; and afterwards, a second electrode material layer is prepared on a surface of a structure of the prepared phase-change material layer, so as to prepare a phase-change memory unit; where phase-change material layer and the first electrode are isolated from each other by the transition material layer, and the second electrode material layer is in electrical communication with the phase-change material layer.

### BACKGROUND OF THE PRESENT INVENTION

1. Field of Invention

The present invention relates to the field of phase-change memories, and more specifically to a high-speed, high-density, and low-power consumption phase-change memory unit, and a preparation method thereof.

2. Description of Related Arts

In the semi-conductor market, memories are of great importance. At present, the memories are mainly classified: static random access memories (SRAMs), dynamic random access memories (DRAMs), magnetic disks, flash memories (Flashes), and ferroelectric memories. Other memories such as phase change random access memories (PCRAMs) and resistive random access memories (RRAMs), as candidates of the next-generation memory, also receive much attention. In the industry, it is considered that FLASH will encounter restrictions in size. Among various memory technologies that probably replace the current memory technologies and become novel commercial memory technologies, the PCRAM is regarded as one of optimum solutions in the next-generation nonvolatile memory technologies, which has advantages such as a small-size storage unit, nonvolatility, long cycle life, desirable stability, low power consumption, and a strong embeddable function; especially has prominent advantages in reduction of feature size of the device and technical superiority that a node can be minimized to be less than 45 nm. Therefore, international well-known semiconductor companies such as Intel, Samsung, STMicroelectronics, Philips, International Business Machine Corporation, and Elpida spend a lot of manpower and resources to develop such technologies. At present, Samsung has developed a phase-change storage test chip with a capacity up to 8 Gb.

At present, a research hotspot for the phase-change memory is how to realize low power consumption, high speed, high density, and long cycle life of the phase-change memory. In a conventional T-shaped device, 60% to 72% heat is dissipated and lost through a bottom electrode, so the heating efficiency is low, resulting in that a high operating voltage/current is required to implement the storage operation. However, since the phase-change memory needs to be integrated with a metal oxide semiconductor field effect transistor (MOSFET) device and the operating voltage is provided by the MOSFET, due to excessively high operating voltage, the phase-change material device may be incompatible with the MOSFET. In addition, the T-shaped device is oversized, which limits the density of a phase-change memory array; moreover, the size of the device unit is another important factor that affects the operation power consumption of the device, so reduction of the size of the device unit can effectively reduce the area of the phase-change unit and decrease the operation power consumption. In another aspect, the conventional T-shaped device has a limited operation speed, and is difficult to perform a high-speed operation. Since a phase-change material is diffused to the bottom electrode and the surroundings in the process of operation of the phase-change memory, separation of the material ingredients may occur after the device unit is erased and written certain times, so that the reliability of the operation of the device is influenced, resulting in reduced cycle times.

### SUMMARY OF THE PRESENT INVENTION

In view of the disadvantages of the prior art, the present invention is directed to a high-speed, high-density, and low-power consumption phase-change memory unit, and a preparation method thereof

To achieve the objectives and other related objectives, the present invention provides a preparation method of a high-speed, high-density, and low-power consumption phase-change memory unit, which at least comprises the following steps:

A. preparing a transition material layer with an accommodation space on a surface of a structure of a formed first electrode, wherein the accommodation space corresponds to the first electrode;

B. preparing a phase-change material layer on a structure of the formed transition material layer, and enabling the phase-change material layer to be in the accommodation space; and

C. preparing a second electrode material layer on a surface of a structure of the prepared phase-change material layer, so as to prepare a phase-change memory unit.

The phase-change material layer and the first electrode are isolated from each other by the transition material layer, and the second electrode material layer is in electrical communication with the phase-change material layer.

Preferably, Step A comprises: preparing a transition material layer with a groove on the surface of the structure of the formed first electrode, wherein the groove covers the first electrode; correspondingly, Step B at least comprises: preparing a phase-change material layer on the transition material layer with a groove, so that the phase-change material layer is located in the groove.

Preferably, in Step A, the transition material layer with an accommodation space is prepared through an atom-layer deposition (ALD) process.

The present invention further provides a high-speed, high-density, and low-power consumption phase-change memory unit, which at least comprises:

a substrate, a first electrode formed on the substrate, a transition material layer with an accommodation space and covering the first electrode, a phase-change material layer in the accommodation space, and a material layer comprising a second electrode and formed on a surface of the transition material layer, wherein the phase-change material layer and the first electrode are isolated from each other by the transition material layer, and the second electrode is in electrical communication with the phase-change material layer.

Preferably, the accommodation space is in a groove shape.

Preferably, the thickness of the transition material layer is in the range of 1 nm to 10 nm.

Preferably, a material used in the transition material layer comprises a material facilitating nucleation growth of the phase-change material, and having a desirable thermal stability, a low thermal conductivity, and a desirable adhesion, such as GeN, SiO₂, TiO₂, Al₂O₃, HfO₂, Ta₂O₅, and Si₃N₄.

As described above, the high-speed, high-density, and low-power consumption phase-change memory unit of the present invention has the following beneficial effects: (1) the introduction of the transition material layer, in one aspect, reduces heat dissipation and atom diffusion, thereby improving the heating efficiency and effectively reducing the operation power consumption; in another aspect, the interfacial effect of the transition material layer facilitates the nucleation growth of the phase-change material, thereby effectively increasing the speed of the device; (2) the structure of such a storage unit is simple, thereby facilitating reduction of the size of the device in equal proportion, and making high density possible; (3) the small-size device unit can inhibit the growth of crystal grains, inhibit atom diffusion, and facilitate reversible phase change of the short-range phase-change material; the multi-interface transition material layer that promotes the nucleation growth also facilitates the nucleation growth of the phase-change material, thereby effectively increasing the phase change speed; and (4) the transition material layer inhibits diffusion of the phase-change material to the electrode material and ensures the consistency of materials in the device unit after multiple operations; due to the uniform electric field, the operating current is low, and the power consumption low, thereby effectively inhibiting ingredient separation during conversion from the polycrystalline state to the non-crystalline state, thereby facilitating prolonging of service life of the device, reducing interference, and facilitating high-density integration.

### BRIEF DESCRIPTION OF THE DRAWINGS

FIG. 1 to FIG. 10 are flowcharts of a preparation method of a high-speed, high-density, and low-power consumption phase-change memory unit of the present invention.

### LIST OF THE NUMERALS

1. Substrate
2. SiO₂ layer
3. Bottom electrode
4. Sift layer
5. Transition material layer
6. Phase-change material layer
7. TiN electrode layer
8. TiN electrode layer

### DETAILED DESCRIPTION OF THE PREFERRED EMBODIMENTS

The implementation of the present invention is described in the following through specific examples, and persons skilled in the art can easily understand other advantages and effects of the present invention through the content disclosed in the specification. The present invention may also be executed or applied through other different examples, modifications and variations may be made to the details in the specification on the basis of different opinions and applications without departing from the principle of the present invention.

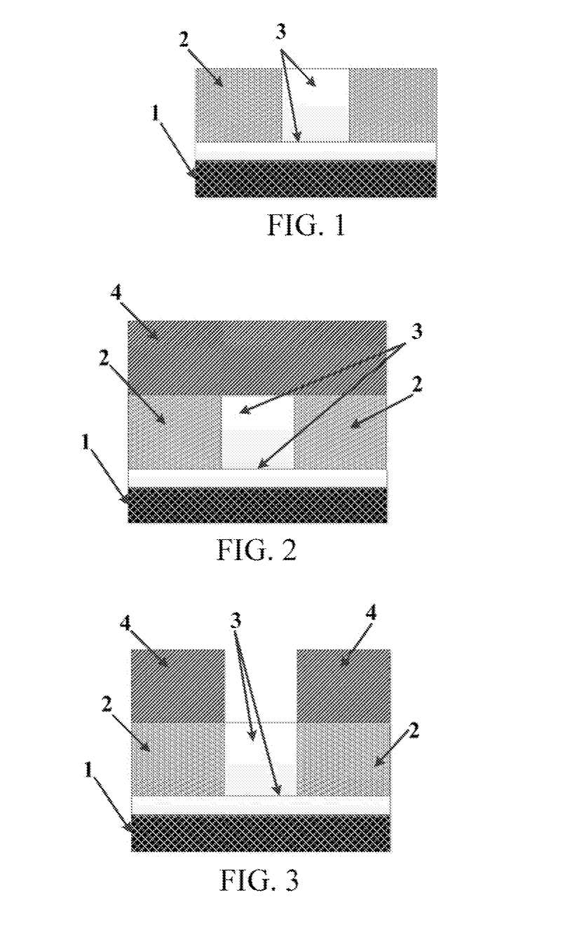

Referring to FIG. 1 to FIG. 10, it should be noted that, the drawings provided in the embodiment merely exemplarily describes a basic concept of the present invention, so components related to the present invention are merely shown in the drawings, but are not drawn according to the number, shapes and size of the components in actual implementation. The shape, the number and the size of the components can be changed at will in the actual implementation, and the layout type of the components may be more complicated.

A preparation method of a high-speed, high-density, and low-power consumption phase-change memory unit of the present invention includes the following steps.

(1) A substrate structure including a first electrode is selected.

For example, as shown in FIG. 1, the substrate structure includes an Si substrate 1, an inverted-T bottom electrode 3 (that is, the first electrode), and an SiO₂ layer 2, where a material of the bottom electrode 3 is w.

(2) A dielectric material layer is deposited on the substrate by using an ultra-high vacuum electron beam evaporation method. Preferably, the thickness of the dielectric material is in the range of 20 nm to 100 nm.

For example, the substrate structure is cleaned 3 minutes in the presence of ultrasound by using a solution of acetone and alcohol respectively, and then is baked for 20 minutes at 80° C.; afterwards, an SiO₂ layer 4 (that is, the dielectric material layer) is deposited on the substrate structure by using an ultra-high vacuum electron beam evaporation method, where the thickness is in the range of 20 nm to 100 nm, as shown in FIG. 2, and the vacuum pressure adopted during evaporation is 2×10⁻⁵ Pa.

(3) Pores reaching the first electrode on the dielectric material layer are prepared by adopting a micro-nano machining technology, where the micro-nano machining technology includes ultraviolet exposure, developing, reactive ion etching, and focused ion beam etching. Preferably, the pore is in a cuboid structure or a cylinder structure, a side wall of the pore is perpendicular to the first electrode, where the length and the width of the cuboid are in the range of 5 nm to 100 nm, the diameter of the cylinder is in the range of 5 nm to 100 nm, and the height of the pore is the same as the thickness of the dielectric material.

For example, a series of pores reaching the bottom electrode 3 are prepared on the Sift layer 4 through etching by using a focused ion beam, a top view of the pore is a square with a side length in the range of 20 nm to 100 nm, as shown in FIG. 3.

(4) A transition material layer with an accommodation space is deposited on the dielectric material layer with pores by using an ALD system, where the accommodation space corresponds to the first electrode.

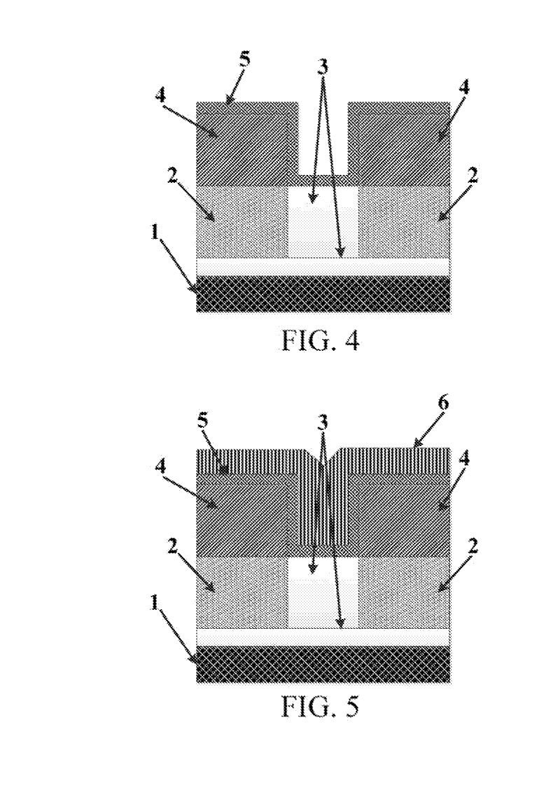

For example, a transition material layer 5 with an accommodation space is deposited on the SiO₂ layer 4 by using the ALD system, where the accommodation space is in a groove shape, and a bottom portion of the accommodation space contacts the bottom electrode 3. Preferably, a material of the transition material layer 5 includes a material facilitating nucleation growth of the phase-change material, and having desirable thermal stability, low thermal conductivity, and desirable adhesion, for example, includes one of TiO₂, Al₂O₃, HfO₂, Ta₂O₅, SiO₂, and Si₃N₄, the thickness preferably is in the range of 1 nm to 10 nm, as shown in FIG. 4.

(5) A phase-change material layer is further deposited on the transition material layer 5 through physical vapor deposition (PVD), chemical vapor deposition (CVD), or ALD. Preferably, the thickness of the phase-change material is in the range of 20 nm to 100 nm.

For example, a phase-change material layer 6 is further deposited on the transition material layer 5 through PVD, and the thickness is preferably is in the range of 20 nm to 100 nm, as shown in FIG. 5. The material of the phase-change material 5 includes one of Ge—Sb—Te, Si—Sb—Te, Sb—Te, Al—Sb—Te, and Ti—Sb—Te, and may also be a compound obtained after modification through doping of one or two elements from N, O, Sn, Ag, and In.

(6) The phase-change material and the transition material layer 5 on the dielectric material layer are removed by adopting a polishing technology, until the dielectric material layer is exposed.

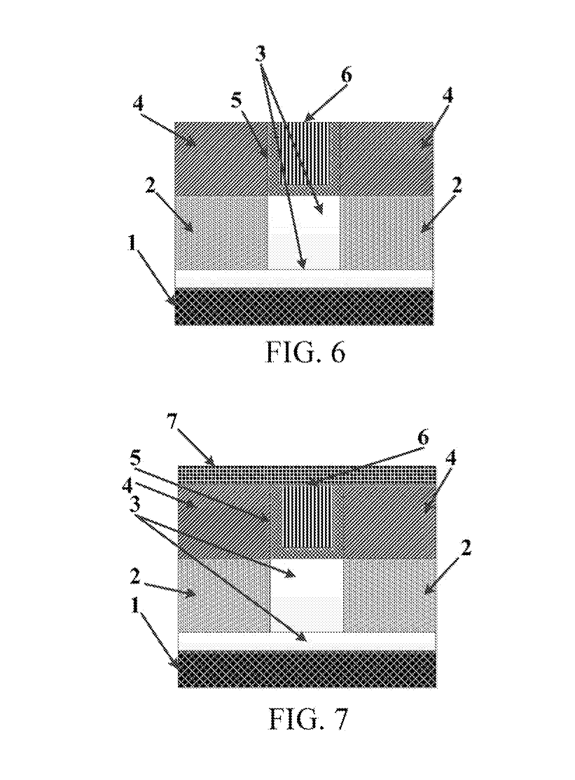

For example, the phase-change material and the transition material layer 5 on the SiO₂ layer 4 are removed by adopting a chemical mechanical polishing method, so that the remained phase-change material layer 6 is totally located in the accommodation space (that is, the groove), and then the polished structure is immersed and cleaned in a solution of acetone and alcohol, as shown in FIG. 6.

(7) A TiN electrode layer is deposited on the transition material layer 5 in a groove shape through PVD or ALD, and the TiN electrode layer is etched by adopting a micro-nano machining technology. Preferably, the TiN electrode layer is also perpendicular to the side wall of the transition material layer 5.

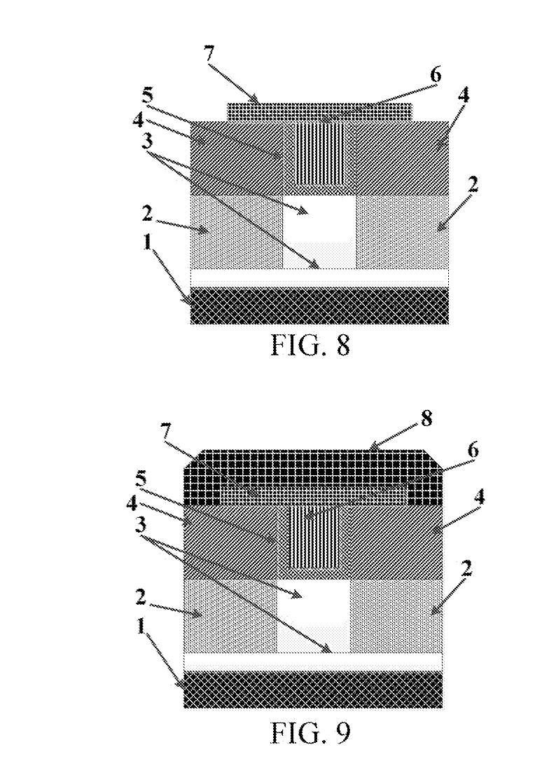

For example, a TiN electrode material layer 7 is deposited on a surface of the transition material layer 5 in a groove shape through PVD, where the thickness of the TiN electrode layer is in the range of 5 nm to 20 nm, a top view of the formed TiN electrode unit is a square with a side length in the range of 5 μm to 100 μm, the adopted vacuum pressure is 2×10⁻⁴ Pa, the pressure in vacuum sputtering is 2.1 Pa, and the power is DC 200 W, as shown in FIG. 7. Afterwards, a square with a side length of 3 μm to 5 μm is photo-etched on the TiN electrode material layer 7 through ultraviolet exposure, the TiN electrode material layer 7 is etched by using a reactive ion etching method, to form a TiN columnar structure, and a top view of the columnar structure is a square with a side length of 3 μm to 5 μm, as shown in FIG. 8.

(8) An electrode layer 8 is deposited on the TiN columnar structure by using an ultra-high vacuum electron beam evaporation method, for example, an Al electrode, where the thickness is in the range of 200 nm to 300 nm, a top view of the formed Al electrode unit is a square with a side length in the range of 5 μm to 100 μm, as shown in FIG. 9.

(9) The Al electrode layer is corroded by adopting a micro-nano machining technology, and upper and lower electrode pins are led out.

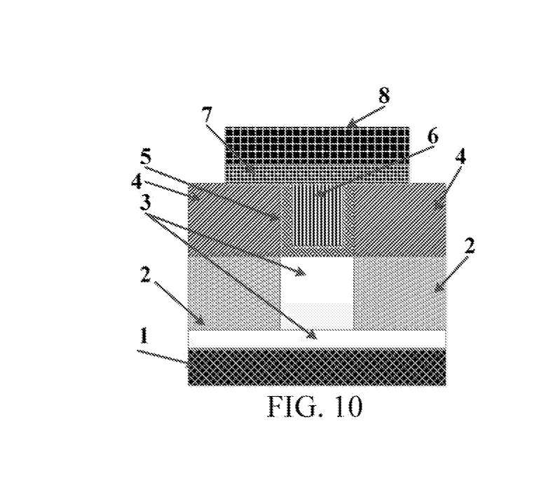

For example, a square with a side length in the range of 3 μm to 5 μm is photo-etched on the Al electrode layer through ultraviolet exposure, and is baked for 20 minutes at 120° C.; then, wet etching is performed on the Al electrode layer in a water bath in the presence of phosphoric acid at 60° C., and upper and lower electrodes are led out at the same time, thereby completing the preparation of the phase-change memory unit, as shown in FIG. 10.

It can be seen from the above that, the prepared high-speed, high-density, and low-power consumption phase-change memory unit at least includes: a substrate 1, a first electrode 3 and SiSiO₂ layer formed on the substrate 1, a transition material layer 5 with an accommodation space and covering the first electrode 3, a phase-change material layer 6 in the accommodation space, and a second electrode material layer (formed by a TiN electrode layer and an Al electrode layer in this embodiment) formed on a surface of the transition material layer 6. It can be seen from FIG. 10 that, the phase-change material layer 6 and the first electrode 3 are isolated from each other by a bottom portion of the transition material layer 5 in a groove shape, and the second electrode is in electrical communication with the phase-change material layer 6.

To sum up, in the high-speed, high-density, and low-power consumption phase-change memory unit of the present invention, the transition material layer is used between the bottom electrode and the phase-change material, and the transition material layer has stable physical properties (resistivity, thickness of the film, roughness of the film, thermal conductivity, and specific heat capacity) in a temperature range from room temperature to a temperature higher than the melting point of the phase-change material, and has good adhesion to the bottom electrode, the phase-change material, and the surrounding dielectric material layer. Therefore, heat dissipation to the bottom electrode can be effectively reduced, and heat can be stored in the phase-change material, thereby reducing the power consumption and improving the heating efficiency. In addition, the small-size pores are prepared through reactive ion beam etching, and then the uniform transition layer material and the phase-change material are deposited through ALD, thereby reducing the size of the device unit and reducing the power consumption. Moreover, the transition layer material can effectively inhibit diffusion of the phase-change material to the bottom electrode in a W direction, and no chemical reaction occurs between the transition layer material with the phase-change material and the bottom electrode, thereby ensuring the consistency of operation during cycle operation of the device, improving the reliability of the device, and prolonging the service life of the device. Therefore, the present invention effectively overcomes the disadvantages in the prior art, and has a high industrial value in use.

The description of the above embodiments is only to illustrate the principle and effect of the present invention, but is not intended to limit the present invention. Any persons skilled in the art can make modification or variation to the above embodiments without departing from the spirit and scope of the present invention. Any equivalent modification and change made by persons with ordinary skill in the art without departing from the spirit and technical thought disclosed in the present invention shall all fall within the scope of claims of the present invention.

1. A preparation method of a high-speed, high-density, and low-power consumption phase-change memory unit, at least comprising:
A. preparing a transition material layer with an accommodation space on a surface of a structure of a formed first electrode, wherein the accommodation space corresponds to the first electrode;
B. preparing a phase-change material layer on a structure of the formed transition material layer, and enabling the phase-change material layer to be in the accommodation space; and
C. preparing a second electrode material layer on a surface of a structure of the prepared phase-change material layer, so as to prepare a phase-change memory unit;
wherein the phase-change material layer and the first electrode are isolated from each other by the transition material layer, and the second electrode material layer is in electrical communication with the phase-change material layer.

2. The preparation method of a high-speed, high-density, and low-power consumption phase-change memory unit as in claim 1, wherein Step A comprises:
preparing a transition material layer with a groove on the surface of the structure of the formed first electrode, wherein the groove covers the first electrode; and
Step B at least comprises:
preparing a phase-change material layer on the transition material layer with a groove, so that the phase-change material layer is located in the groove.

3. The preparation method of a high-speed, high-density, and low-power consumption phase-change memory unit as in claim 1, wherein in Step A, the transition material layer with an accommodation space is prepared through an atom-layer deposition (ALD) process.

4. The preparation method of a high-speed, high-density, and low-power consumption phase-change memory unit as in claim 1, wherein a material used in the transition material layer comprises a material facilitating nucleation growth of the phase-change material, and having a desirable thermal stability, a low thermal conductivity, and a desirable adhesion.

5. The preparation method of a high-speed, high-density, and low-power consumption phase-change memory unit as in claim 4, wherein the material of the transition material layer comprises one of GeN, SiO₂, TiO₂, Al₂O₃, HfO₂, Ta₂O₅, and Si₃N₄.

6. A high-speed, high-density, and low-power consumption phase-change memory unit, at least comprising:
a substrate, a first electrode formed on the substrate, a transition material layer with an accommodation space and covering the first electrode, a phase-change material layer in the accommodation space, and a second electrode material layer forming on a surface of the transition material layer, wherein the phase-change material layer and the first electrode are isolated from each other by the transition material layer, and the second electrode material layer is in electrical communication with the phase-change material layer.

7. The high-speed, high-density, and low-power consumption phase-change memory unit as in claim 6, wherein the accommodation space is in a groove shape.

8. The high-speed, high-density, and low-power consumption phase-change memory unit as in claim 6, wherein the thickness of the transition material layer is in the range of 1 nm to 10 nm.

9. The high-speed, high-density, and low-power consumption phase-change memory unit as in claim 6, wherein a material of the transition material layer comprises a material facilitating nucleation growth of the phase-change material, and having a desirable thermal stability, a low thermal conductivity, and a desirable adhesion.

10. The high-speed, high-density, and low-power consumption phase-change memory unit as in claim 9, wherein the material of the transition material layer comprises one of GeN, SiO₂, TiO₂, Al₂O₃, HfO₂, Ta₂O₅, and Si₃N₄.

11. The preparation method of a high-speed, high-density, and low-power consumption phase-change memory unit as in claim 2, wherein in Step A, the transition material layer with an accommodation space is prepared through an atom-layer deposition (ALD) process.

12. The preparation method of a high-speed, high-density, and low-power consumption phase-change memory unit as in claim 2, wherein a material used in the transition material layer comprises a material facilitating nucleation growth of the phase-change material, and having a desirable thermal stability, a low thermal conductivity, and a desirable adhesion.

13. The high-speed, high-density, and low-power consumption phase-change memory unit as in claim 7, wherein the thickness of the transition material layer is in the range of 1 nm to 10 nm.
